(19) United States
(12) Patent Application Publication
(10) Pub. No.: US 2005/0089179 A1
(43) Pub. Date: Apr. 28, 2005

(54) Car audio amplifier with remote control panel

(76) Inventor: Claudio R. Laraia, Yorktown, NY (US)

Correspondence Address: RICHARD C. CALDERWOOD, 2775 NW 126TH AVE, PORTLAND, OR, 97229-8381, US

(21) Appl. No.: 10/693,569

(22) Filed: Oct. 24, 2003

(51) Int. Cl. H03F 21/00; H04B 1/00

(52) U.S. Cl. 381/120; 381/86

(57) ABSTRACT

A car audio system in which the gain, low/high pass filter, etc. controls are located on a separate control unit rather than on an external amplifier. The external amplifier can be mounted e.g. in the trunk, with the control unit being mounted in the dash with the head unit, enabling adjustment of the various settings from the actual listening position. Optionally, the control unit can be removed from its more convenient location and docked directly into the external amplifier, after an acceptable initial set of control settings is achieved.

### BACKGROUND OF THE INVENTION

1. Technical Field of the Invention

This invention relates generally to audio electronics, and more specifically to an amplifier with a remote control panel which contains the adjustment controls for the amplifier.

2. Background Art

FIG. 1 illustrates a front perspective view of a conventional car stereo system 10. The stereo system includes a head unit 12 which receives radio broadcasts, plays compact discs, and so forth. The head unit includes a master volume control 14 and various other controls. The setting of the master volume control determines the level of all of the pre-amp signals which are sent to an external amplifier 16 via one or more cables 18. The external amplifier amplifies these signals and drives them to drive a set of audio loudspeakers (not shown). The loudspeakers are connected via speaker wires (not shown) to amplifier output terminals 20. The stereo may optionally also include a remote bass boost control pod 22 which is connected to the external amplifier by a cable 24 which is generally a CAT5 cable or a custom cable. The bass boost control is only a single-band equalizer which adjusts the relative volume of one preset low bass frequency, independently of and in addition to the effect of the head unit's master volume control.

FIG. 2 illustrates a rear perspective view of the stereo system 10. The head unit 12 receives electric power at power terminals 26, and the external amplifier receives electric power at power terminals 28. The pre-amp level signals are carried over RCA cables 18 which are coupled between RCA output jacks 30 on the head unit and RCA input jacks 32 on the external amplifier. A cable 34 carries a “remote on” signal from the head unit to the external amplifier which causes the external amplifier to turn on. This same signal is commonly also routed to a power antenna (not shown), which extends when the signal is asserted and retracts when the signal is deasserted.

FIGS. 3 and 4 illustrate the front and rear of the head unit 12 in closer detail. In addition to the master volume control, the head unit typically also includes a plurality of radio station preset buttons (labeled 1 through 8), a display of some sort, a compact disc player (at the slot labeled CD), a cassette tape player (not shown), and so forth in various combinations and permutations. Some head units are “stereo only”, meaning that they have outputs for a Left channel and a Right channel. More advanced head units are providing more channels, such as Front Left (FL), Front Right (FR), Center (C), Rear Left (RL), Rear Right (RR), and Subwoofer (SUB). Additionally, some head units have input terminals for receiving signals from external sources, such as an external MP3 player, suggested by the auxiliary input terminals 36 (AUX IN L/R). The head unit may optionally have a DIN connector 38 or, more frequently, simply a bundle of wires extending out the back. A connector 40 or, similarly, a wire, provides the remote on signal for the external amplifier and the power antenna.

FIGS. 5 and 6 illustrate the front and rear of the external amplifier 16 in closer detail, including the speaker output terminals 20, power terminals 28, audio signal input connectors 32, and remote on input terminal or wire 42. The head unit's master volume control turns the pre-amp level signals up and down together. Most quality stereo systems have additional controls beyond the master volume control, which is necessary but inadequate alone for achieving a balanced, pleasing sound. These are generally located on the external amplifier, and therein lies a problem.

There are several sources of sound reproduction differences between the various audio channels. The loudspeakers are often not identical; for example, the car may have a set of small circular speakers mounted in the front doors and driven by the Front Left and Front Right signals, but a set of larger and more powerful speakers mounted in the rear deck and driven by the Rear Left and Rear Right signals. Or, the front speakers may be coaxial speakers which include tweeters, while the rear speakers may be conventional woofers. The length of the wires driving the front speakers may be significantly shorter than the length of the wires driving the rear speakers, or vice versa. The front speakers may have 2 ohm voice coils, and the rear speakers may have 4 ohm voice coils. The amplifier may provide 50 watts per channel to the Front and Rear channels, but 400 watts to the Subwoofer channel. The head unit itself may have a design flaw or manufacturing defect which causes a single channel to have a noticeably quieter or brighter signal, and so forth.

To help the installer and user overcome these limitations, the external amplifier is generally provided with one or more controls 44 for each channel. By way of illustration only, the Front, Center, and Rear channels may have Gain (G) controls and High Pass Filter (HPF) controls, and the Subwoofer channel may have a Gain control and a Low Pass Filter (LPF) control.

However, because these channel signal controls are located on the external amplifier, which is typically located in an inconvenient spot such as inside the trunk of a car, behind the seat of a truck, or under the rear seat of an SUV, it is very difficult for the installer to achieve an optimal setting for the set of controls as a whole and with respect to each other. The installer is unable to e.g. sit in the driver's seat of a commuter's car and adjust a single channel's gain up and down repeatedly, until his ear says the right result has been obtained. Rather, he has to sit in the driver's seat, listen, get out of the car, go to the trunk, adjust the control, get back in the car, and listen again, repeating this process until a somewhat decent result has been obtained or, more typically, until he succumbs to the fact that he is being paid by the job and not by the hour.

However, it is generally quite impractical and undesirable to mount the external amplifier in a location which would be easily accessible during the installation and initial setup. External amplifiers are generally quite large, and do not readily fit into convenient places inside the passenger compartment of many vehicles. Furthermore, external amplifiers can produce significant amounts of heat and significant surface temperatures. It would be most undesirable to have a large, heat-producing amplifier directly under a driver's legs in Phoenix during July. It would be even more undesirable to have a dangerously hot amplifier located where children might touch it at any time.

What is needed, then, is an improved stereo system which decouples the heat-producing aspects of the external amplifier from its control settings.

### BRIEF DESCRIPTION OF THE DRAWINGS

The invention will be understood more fully from the detailed description given below and from the accompanying drawings of embodiments of the invention which, however, should not be taken to limit the invention to the specific embodiments described, but are for explanation and understanding only.

FIG. 1 shows a front perspective view of a conventional car stereo system according to the prior art.

FIG. 2 shows a rear perspective view of the prior art car stereo system.

FIGS. 3 and 4 show front and rear perspective views of a conventional head unit.

FIGS. 5 and 6 show front and rear perspective views of a conventional external amplifier.

FIGS. 7 and 8 show front and rear perspective views of one embodiment of a separate control unit for an external amplifier according to this invention.

FIG. 9 shows a perspective view of one embodiment of an external amplifier according to this invention.

FIG. 10 shows a perspective view of one embodiment of an external amplifier according to this invention, having its remote control unit docked into the external amplifier.

FIGS. 11 and 12 show front and rear perspective views of one embodiment of a car stereo system according to this invention.

FIG. 13 shows a rear perspective view of one embodiment of a car stereo system according to this invention, with the amplifier control unit docked into the amplifier.

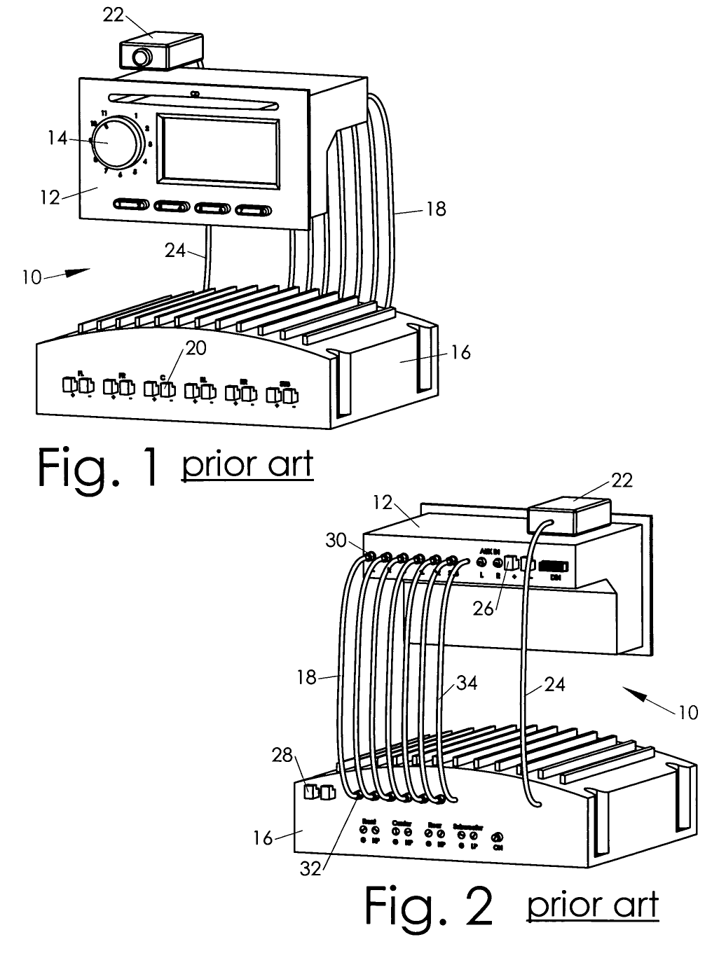

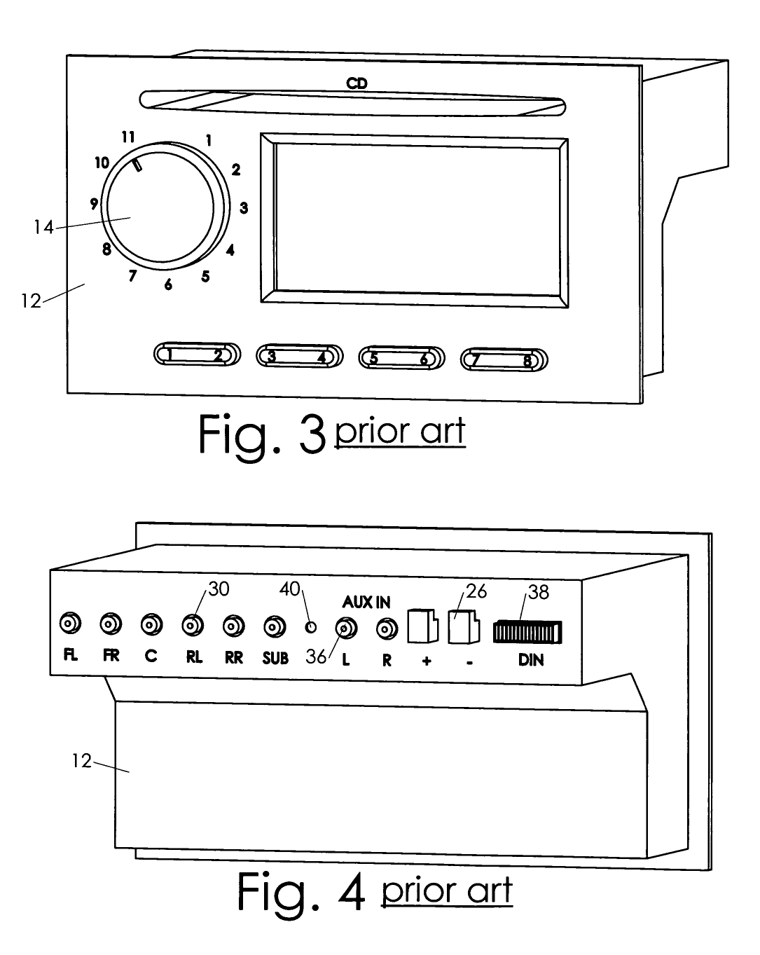

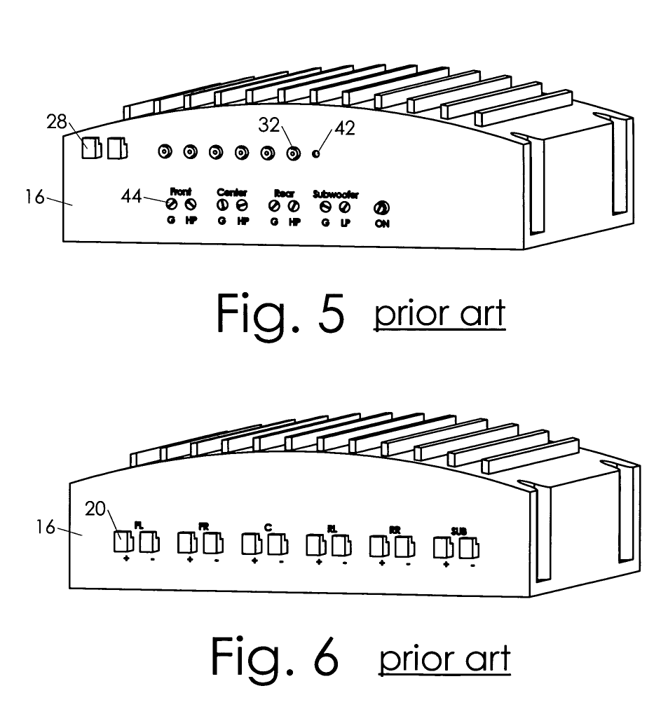

### DETAILED DESCRIPTION

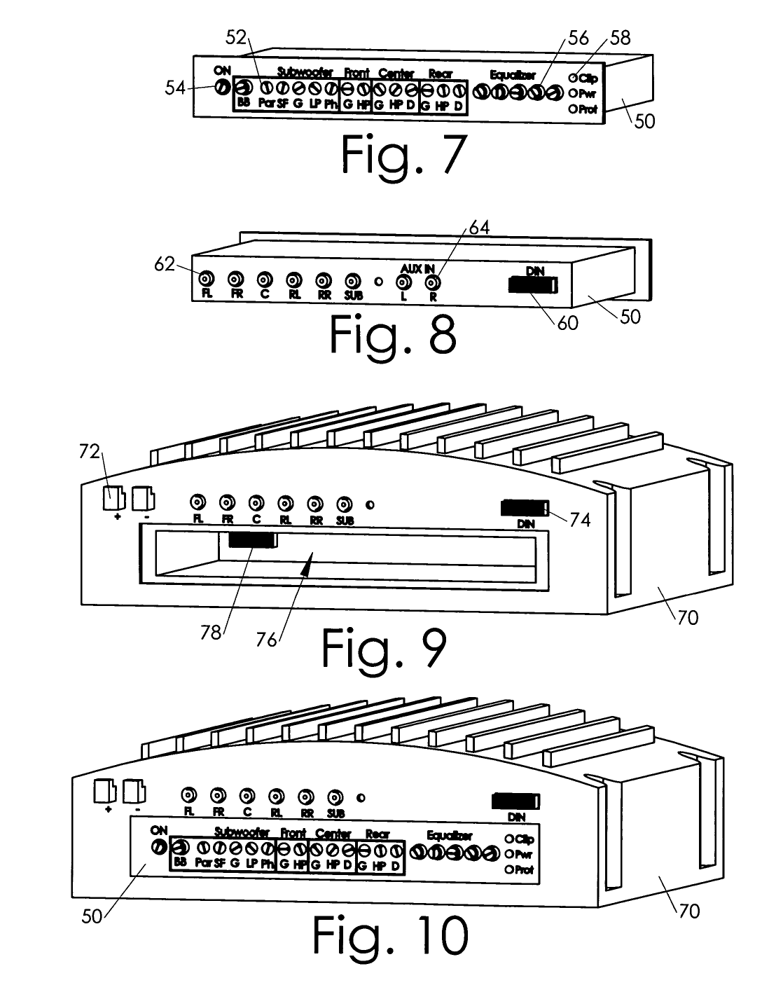

FIG. 7 illustrates one embodiment of a separate control unit 50 for controlling channel parameter settings of an external amplifier (not shown) such as may be used in a car audio system. The control unit includes controls 52 for setting various parameters of one or more channels of audio signal. In various embodiments, controls are provided for a 1-, 2-, 3-, 4-, 5-, 6-, or 7-channel (or more) external amplifier. The control unit also includes the pre-amplifier electronics (not shown).

The drawing illustrates controls for a 6-channel system, including Front (F) (with Left and Right controlled together), Center (C), Rear (R) (with Left and Right controlled together), and Subwoofer (SUB) channels. The Front channels are equipped with Gain and High Pass Filter controls. The Center channel is equipped with Gain, High Pass Filter, and Delay controls, as are the Rear channels. The Subwoofer channel is equipped with Gain, Bass Boost, Subsonic Filter, Low Pass Filter, Phase, and Parametric controls.

Additionally, an input selector switch 54 is provided to select either the 5.1 inputs or the stereo auxiliary in inputs, for example. The control unit also has optional equalizer controls 56. Indicator lights 58 are provided to indicate that the external amplifier and the control unit are on or off, that an over-power protection circuit has been activated, and whether the amplifier is being overdriven and is clipping.

FIG. 8 illustrates the rear of the control unit 50. The rear panel includes a DIN output (and, optionally, input) connector 60, one to seven (or more) channel signal input terminals 62 such as RCA connectors, and, optionally, one or more auxiliary input terminals 64 such as RCA jacks. In operation, the control unit receives audio channel signals at the RCA inputs 62, processes those signals according to the various settings of the controls (52, 54, 56 in FIG. 7), optionally performs pre-amplification, and outputs the resulting audio channel signals to the DIN output 60. If the two-channel AUX IN input is selected (per control 54), the two-channel signals are, in some embodiments, converted to the maximum number of channels which the amplifier supports. For example, the Left auxiliary input channel may be fed to the Front Left and Rear Left channels at the DIN output, the Right auxiliary input channel may be fed to the Front Right and Rear Right channels, and the Left and Right auxiliary input channels may be combined and sent to the Center and Subwoofer channels.

FIG. 9 illustrates one embodiment of an external amplifier 70 according to this invention. The external amplifier includes power terminals 72 for receiving electrical power, RCA input connectors 73, a DIN input connector 74, and speaker output terminals (not shown) to which the amplified audio signals are driven. Thus, the amplifier includes dual, parallel inputs—the RCA jacks and the DIN connector—over which the amplifier can receive audio signals for amplification.

Optionally, the external amplifier may also include a docking bay 76 for receiving the control unit. The docking bay includes a DIN connector 78 positioned to mate with the control unit's DIN connector directly or with an intermediate cable; alternatively, it could have RCA jacks (not shown) for mating with the RCA connectors of the control unit. The primary DIN input 74 and the docking bay DIN input 78 may also be considered as being dual, parallel inputs over which the amplifier can receive audio signals for amplification, as may the docking bay DIN input and the RCA jacks. In some embodiments, all three inputs are present, in parallel, although, typically, the amplifier will only amplify audio signals from a single input source at a time.

FIG. 10 illustrates the external amplifier 70 with the control unit 50 docked. This docking option may prove useful if, for example, the car does not have a suitable mounting location for the control unit, or if the user does not wish to be bothered with it after initial setup of the system. In that case, the control unit can be temporarily located inside the vehicle and coupled to the external amplifier via a DIN umbilical cable, the controls can be dialed in to the desired acoustic result from within the passenger compartment, and then the control unit can be moved to the trunk and docked with the amplifier, with the DIN umbilical cable being removed entirely. During subsequent operation, the control unit will continue to control operation of the amplifier and adjustment of the various channel signals, just as if it were mounted in e.g. the dash or console, but the driver will not be able to make adjustments to the gain etc. settings without directly accessing the external amplifier where the control unit is docked.

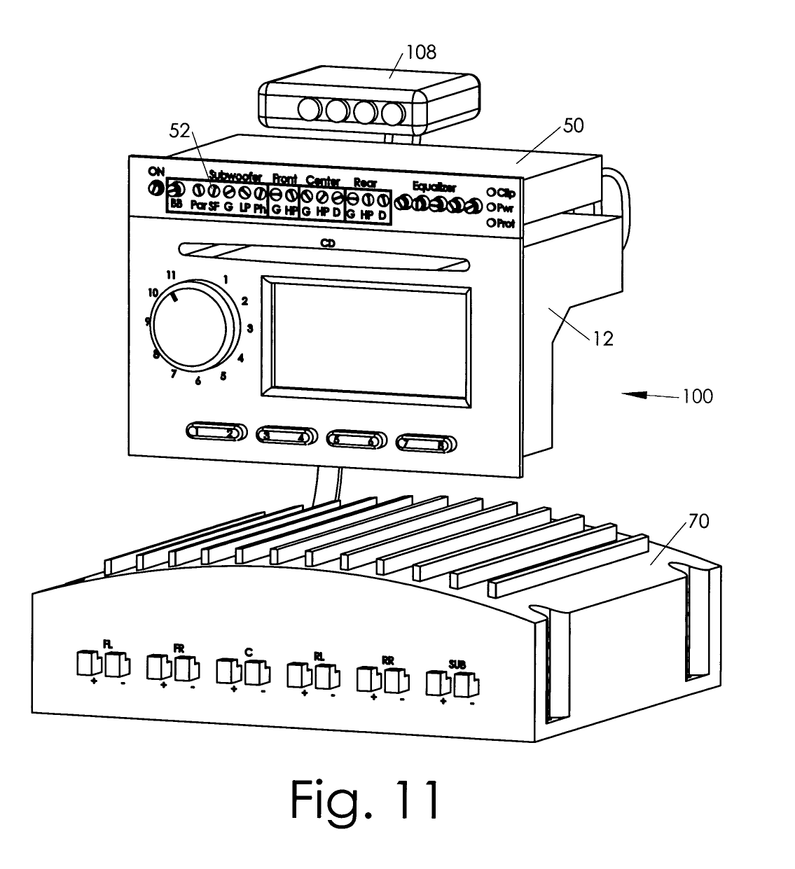

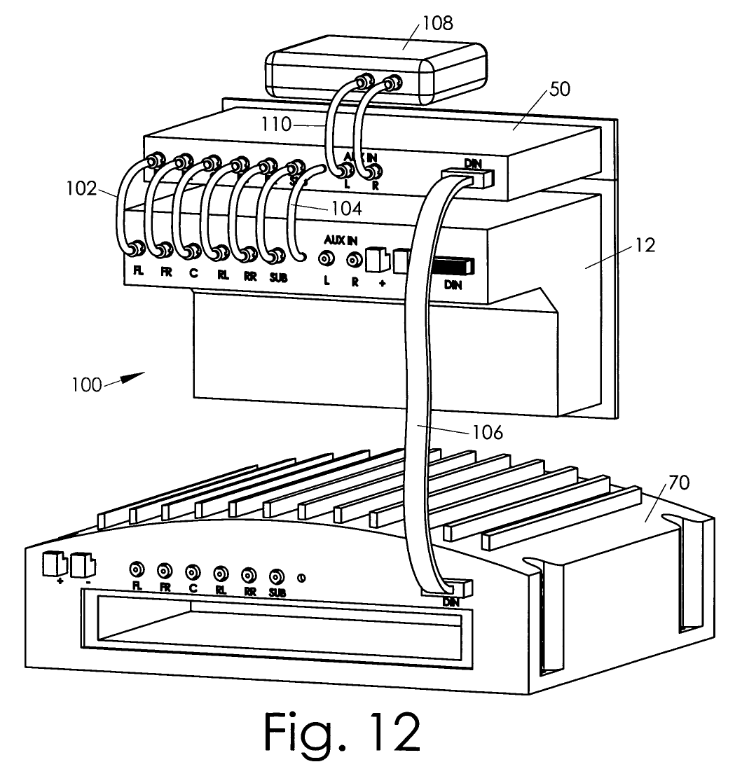

FIGS. 11 and 12 illustrate a car stereo system 100 according to one embodiment of this invention. The stereo system includes a head unit 12 which provides channel signals. The channel signals are routed from the head unit to the remote control unit 50 via cables 102. The remote on signal is routed from the head unit to the remote control unit via cable 104. The control unit applies the gain etc. settings which the user has dialed in with the controls 52, and the control unit then sends modified audio channel signals to the external amplifier 70 via a DIN umbilical cable 106. If an auxiliary unit 108 is present, such as a portable MP3 player, it is connected to the AUX IN inputs of the control unit via cables 110.

In some embodiments, all of the external amplifier controls are located on the remote unit, with the external amplifier itself providing only the amplification function. In other embodiments, a subset of the controls are on the remote unit, while others are located directly on the amplifier; for example, it may be acceptable to locate the high and low pass filter controls on the external amplifier, and only burden the control unit with the gain, delay, and other controls which are far better adjusted from the listening position.

Other permutations have not been illustrated, but are considered within the scope of this invention. For example, a set of predetermined equalizer settings could be built into the control unit, such as a jazz setting, a classical setting, a rock and roll setting, a country and western setting, and a talk radio setting. In some instances, it may be desirable to have these settings in some measure override the settings of various ones of the controls (52); for example, a rap or hip-hop setting may override the setting of the subwoofer gain and bass boost controls, and substitute predetermined settings instead.

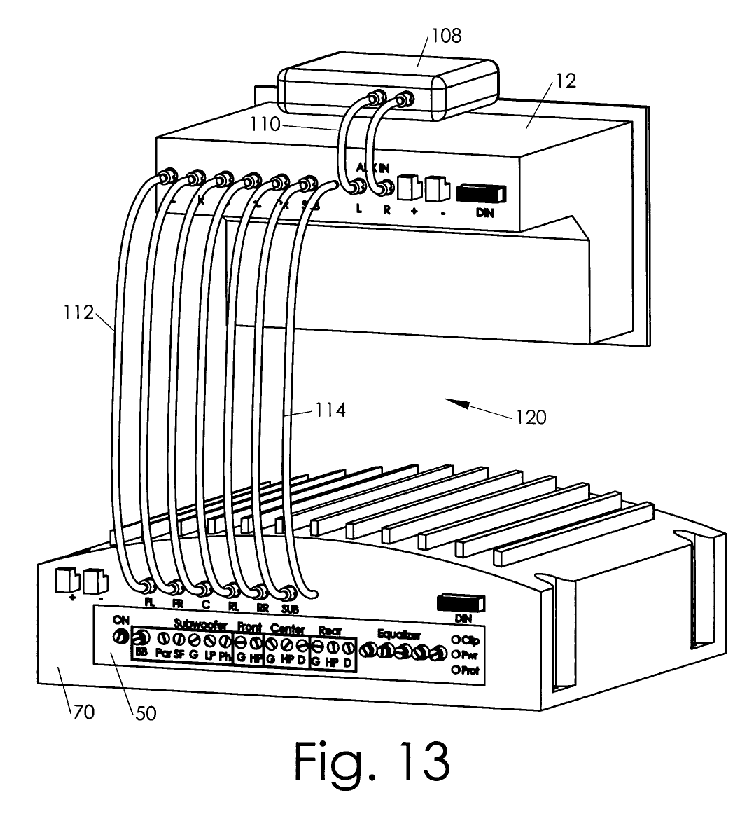

FIG. 13 illustrates a car stereo system 120 utilizing the docking option. The head unit 12 is coupled to send audio channel signals directly to the external amplifier 70 via cables 112 and a remote on signal via a cable 114. An optional auxiliary device 108 is coupled to the head unit by cables 110, in which case the user must rely on the head unit's AUX capabilities to e.g. compensate for the output signal strength of the auxiliary device and route its signals through to the outputs on the cables 112. The control unit 50 is docked inside the external amplifier, where it continues to perform its control setting functions, but where it is perhaps less accessible to the user than if it were e.g. mounted in the dash with the head unit.

### Conclusion

When one component is said to be “adjacent” another component, it should not be interpreted to mean that there is absolutely nothing between the two components, only that they are in the order indicated. The various features illustrated in the figures may be combined in many ways, and should not be interpreted as though limited to the specific embodiments in which they were explained and shown. Those skilled in the art having the benefit of this disclosure will appreciate that many other variations from the foregoing description and drawings may be made within the scope of the present invention. Indeed, the invention is not limited to the details described above. Rather, it is the following claims including any amendments thereto that define the scope of the invention.

1. A car audio amplifier system comprising:
(A) a control unit including,
(1) at least one input connector for receiving at least one respective channel of audio signal from a source,
(2) circuitry, coupled to receive the audio signal from the input connector, for modifying the received audio signal;
(3) at least one control for determining a characteristic of the modifying; and
(4) at least one output connector for outputting the modified audio signal; and
(B) an amplifier unit physically separate from, and couplable to, the control unit and including,
(1) an input connector for receiving the modified audio signal output from the control unit,
(2) amplification circuitry coupled to the input connector for amplifying the modified audio signal, and
(3) an output connector for outputting the amplified modified audio signal to a loudspeaker.

2. The car audio amplifier system of claim 1 wherein:
the circuitry of the control unit includes a pre-amplifier.

3. The car audio amplifier system of claim 1 wherein:
the input connector of the control unit is further for receiving at least two channels of audio signal from the source;
the output connector of the control unit is further for outputting at least two channels of modified audio signal; and
the circuitry of the control unit includes means for combining two channels of audio signal from the source and providing the combined signal to one channel at the output connector of the control unit.

4. The car audio amplifier system of claim 3 wherein:
the two channels of audio signal from the source include a Left channel and a Right channel; and
the circuitry of the control unit provides a modified Left channel signal to a Front Left channel and a Rear Left channel at the control unit's output connector, a modified Right channel signal to a Front Right channel and a Rear Right channel at the control unit's output connector, and a combination of the modified Left channel signal and the modified Right channel signal to one of a Center channel and a Subwoofer channel at the control unit's output connector.

5. The car audio amplifier system of claim 1 wherein:
the amplifier unit includes a plurality of input connectors; and
the amplifier circuitry amplifies audio signals provided at a selected one of the plurality of input connectors.

6. The car audio amplifier system of claim 5 wherein:
the amplifier unit includes a first input connector comprising a set of RCA jacks, and a second input connector comprising a DIN connector.

7. The car audio amplifier system of claim 1 wherein:
all of the controls of the audio amplifier system are located on the control unit.

8. The car audio amplifier system of claim 1 wherein the characteristic comprises gain.

9. The car audio amplifier system of claim 1 wherein:
the control unit comprises a plurality of controls each for determining a respective one of a plurality of characteristics; and
the plurality of characteristics comprises gain and at least one of high pass filter, low pass filter, delay, phase, subsonic filter, subwoofer parametric frequency, and bass boost.

10. The car audio amplifier system of claim 1 wherein:
the amplifier unit comprises a docking bay adapted for docking the control unit.

11. The car audio amplifier system of claim 10 wherein:
the docking bay comprises an input connector adapted to mate with the output connector of the control unit when the control unit is docked.

12. An amplifier system for use in a vehicle which includes a passenger compartment having a head unit providing a plurality of audio channel signals, the amplifier system comprising:
(A) a control unit adapted to mount in the passenger compartment, and comprising,
a control unit input connector for receiving the plurality of audio channel signals from the head unit,
a plurality of controls including at least a gain control,
circuitry, coupled to the control unit input connector, for modifying the plurality of audio signals in response to settings of the controls, and
a control unit output connector for outputting the plurality of modified audio signals; and
(B) an amplifier unit comprising,
an amplifier input connector coupled to the control unit output connector to receive the modified audio signals,
amplifier circuitry coupled to the amplifier input connector for amplifying the modified audio signals; and
speaker terminals coupled to the amplifier circuitry for outputting the amplified modified audio signals.

13. The amplifier system of claim 12 further comprising:
a cable coupling the amplifier input connector to the control unit output connector.

14. The amplifier system of claim 13 wherein:
the control unit output connector comprises a DIN connector, the amplifier input connector comprises a DIN connector, and the cable comprises a DIN umbilical cable.

15. The amplifier system of claim 12 wherein the plurality of controls comprises all off the amplifier system's gain controls.

16. The amplifier system of claim 12 wherein the plurality of controls further includes a filter control.

17. The amplifier system of claim 16 wherein the plurality of controls further includes a delay control.

18. The amplifier system of claim 17 wherein the plurality of controls further includes a phase control.

19. The amplifier system of claim 18 wherein the plurality of controls further includes a bass boost control.

20. The amplifier system of claim 12 wherein the plurality of controls further includes a master volume control which operates in addition to a gain control of any respective channel.

21. The amplifier system of claim 12 wherein the plurality of controls further includes a multi-channel equalizer.

22. The amplifier system of claim 12 wherein the control unit further includes:
an auxiliary input connector for receiving audio channel signals from an auxiliary unit; and
an input selector control for selecting whether the circuitry modifies the audio channel signals from the input connector or the audio channel signals from the auxiliary input connector.

23. The amplifier system of claim 22 wherein the control unit further includes:
input volume means for compensating for signal level difference between audio channel signals from the input connector and audio channel signals from the auxiliary input connector, whereby when a user switches between the head unit and the auxiliary unit by operating the input selector control, a difference in audio volume from the loudspeakers is controlled.

24. The amplifier system of claim 12 wherein:
the amplifier unit includes a docking bay into which the control unit can be docked; and
means for connecting the control unit output connector to the amplifier input connector.

25. The amplifier system of claim 12 wherein the plurality of audio channel signals provided by the head unit includes Front Left, Front Right, Center, Rear Left, Rear Right, and Subwoofer audio channel signals, and wherein the plurality of controls comprises:
Front gain,
Front high pass filter,
Center gain,
Center high pass filter,
Center delay,
Rear gain,
Rear high pass filter,
Rear delay,
Subwoofer gain,
Subwoofer low pass filter,
Subwoofer phase,
Subwoofer subsonic filter,
Subwoofer parametric frequency, and
Subwoofer bass boost.

26. A method whereby a person adjusts audio characteristics of an audio system, the audio system having a head unit, a control unit coupled to the head unit, an external amplifier coupled to the control unit, and loudspeakers coupled to the external amplifier, all channel gain controls for the amplifier being located on the control unit, wherein the head unit, the control unit, and the loudspeakers are located within a passenger compartment of a vehicle, the method comprising:
being positioned within the passenger compartment;
operating the head unit to provide a plurality of audio channel signals to the control unit;
while listening to sound produced by the loudspeakers which are driven by the external amplifier according to modified audio channel signals from the control unit,
adjusting a control on the control unit, to control a modification by the control unit of one of the audio channel signals provided by the head unit, until a desired acoustic result is obtained by such adjusting.

27. The method of claim 26 wherein:
adjusting the control comprises adjusting a channel gain control.

28. The method of claim 27 wherein:
adjusting the control further comprises adjusting a channel filter control.

29. The method of claim 28 further comprising:
selecting back and forth between audio signals provided by the head unit and audio signals provided by an auxiliary unit; and
adjusting an input level adjustment control on the control unit, to substantially equalize an audio volume produced in response to the audio signals provided by the head unit and an audio volume produced in response to the audio signals provided by the auxiliary unit.

30. The method of claim 26 further comprising:
removing the control unit from the passenger compartment; and
docking the control unit into a docking bay on the external amplifier.
